(19) United States
(12) Patent Application Publication
(10) Pub. No.: US 2024/0116126 A1
(43) Pub. Date: Apr. 11, 2024

(54) ULTRASONIC TRANSDUCER OPERABLE AT MULTIPLE RESONANT FREQUENCIES

(71) Applicant: ASMPT SINGAPORE PTE. LTD., Singapore (SG)

(72) Inventors: Tsz Kit YU, Hong Kong (CN); Ka Shing KWAN, Singapore (SG); Hoi Ting LAM, Hong Kong (CN); Hing Leung LI, Hong Kong (CN)

(21) Appl. No.: 17/963,489

(22) Filed: Oct. 11, 2022

(51) Int. Cl. B23K 20/10; H01L 23/00

(52) U.S. Cl. CPC B23K 20/10; H01L 24/78; H01L 2224/85205

(57) ABSTRACT

An ultrasonic transducer includes an elongated transducer body with an aperture for mounting a piezoelectric driver stack for driving the ultrasonic transducer to operate at a first resonant frequency, a mounting flange for mounting the transducer body to a wire bonding machine, a rigid connecting member having first and second ends which are respectively connected to the mounting flange and the transducer body at a first nodal vibration region of the transducer body when the ultrasonic transducer is operated at the first resonant frequency and a flexible connecting member extending between the mounting flange and the transducer body at a second nodal vibration region of the transducer body when the ultrasonic transducer is operated at the first resonant frequency.

### FIELD OF THE INVENTION

The invention generally relates to multi-resonance ultrasonic transducers used with wire bonding tools, and more specifically to an ultrasonic transducer that is operable at multiple resonant frequencies including an ultra-high resonant frequency up to 300 kHz.

### BACKGROUND

Ultrasonic transducers have been widely used with wire bonding tools to provide wire bonds between semiconductor bond pads and lead frames or carriers during wire bonding operations. Typically, conventional ultrasonic are produced with a single operable resonant frequency for making reliable wire bonds. However, in reality, more than one resonant frequency may be needed during wire bonding operations, and various solutions have been proposed in the prior art to provide an ultrasonic transducer that is operable in practice at more than one resonant frequency.

U.S. Pat. No. 7,137,543B2 proposed an ultrasonic transducer 100A suitable for use at multiple ultrasonic frequencies. Referring to FIG. 1A, the ultrasonic transducer includes an integrated flexure mount scheme 108a-108d for each mounting flange 105, to prevent vibrations from being transmitted from the ultrasonic transducer 100A to a machine bond head of a wire bonding machine to which the ultrasonic transducer 100A is mounted. However, as flexures are a type of structure intentionally weakened in one direction for stress relief, the integrated flexure mount scheme 108a-108d would be lower in stiffness in the weakened direction, i.e., the axial direction of the ultrasonic transducer. This will affect the stability of the ultrasonic transducer 100A, thereby reducing the quality of the wire bonds.

U.S. Pat. No. 5,578,888A proposed an ultrasonic transducer 100E having usable lower and higher resonant frequencies. Such an ultrasonic transducer 100E as shown in FIG. 1B includes an integral unibody with a rectangular aperture in the center of its mass. A multi-frequency stack of transducer drivers 28 is mounted in the rectangular aperture 31 with compression wedges 29. The structure of this ultrasonic transducer 100B, especially the fixed location of the rectangular aperture 31, limits the frequency separation between its higher and its lower resonant frequencies. For the ultrasonic transducer 100B, the higher resonant frequency is only about twice the lower resonant frequency. Thus, this prior art ultrasonic transducer 100B is only operable at a limited frequency range.

U.S. Pat. No. 5,595,328A proposed a self-isolating ultrasonic transducer 100C, which is a low mounting impedance ultrasonic transducer 100C as shown in FIG. 1C, It includes two modified mounting flanges 13 for mounting the ultrasonic transducer 100C on a bonding machine through mounting holes 15. Each modified mounting flange 13 includes an aperture 21, i.e., a stress relief slot, in the mounting flange 13 or a transducer body 14 to isolate transversal radial stress in the transducer body 14 from entering into the mounting flange 13 and coupling to the bonding machine. This ultrasonic transducer 100C cannot operate well at multiple ultrasonic frequencies unless a common mounting node can be identified on the transducer body 14 for the multiple ultrasonic frequencies. Moreover, the stress relief slot on the mounting flange 13 or the transducer body 14 will reduce the bending stiffness of the ultrasonic transducer 100C.

It would therefore be beneficial to provide a new design of ultrasonic transducers that are operable at multiple resonant frequencies which can overcome at least one of the shortcomings in the prior art ultrasonic transducers mentioned above.

### SUMMARY OF THE INVENTION

It is thus an object of the invention to seek to provide an improved multi-resonance ultrasonic transducer that are operable at a first (higher) resonant frequency as well as a second (lower) resonant frequency. The latter may be is less than one third of the first resonant frequency.

According to a first aspect of the present invention, there is provided an ultrasonic transducer configured to operate at a first resonant frequency during wire bonding operations. The ultrasonic transducer comprises an elongated transducer body with an aperture for mounting a piezoelectric driver stack for driving the ultrasonic transducer to operate at the first resonant frequency, a mounting flange for mounting the transducer body to a wire bonding machine, a rigid connecting member having first and second ends which are respectively connected to the mounting flange and the transducer body at a first nodal vibration region of the transducer body when the ultrasonic transducer is operated at the first resonant frequency, and a flexible connecting member extending between the mounting flange and the transducer body at a second nodal vibration region when the ultrasonic transducer is operated at the first resonant frequency. In order to minimize the vibration to be transmitted to the mounting flange when the ultrasonic transducer is operated at the first resonant frequency, both the rigid connecting member and the flexible connecting member are attached to the first and second nodal vibration regions of the transducer body which have a minimum vibration amplitude when the ultrasonic transducer is operated at the first resonant frequency.

In one embodiment, the minimum vibration amplitude may be a vibration amplitude not higher than 10% of a maximum vibration amplitude of the transducer body when the ultrasonic transducer is operated at the first resonant frequency.

In some embodiments, the first nodal vibration region is located closer to a bonding tool compared to the second nodal vibration region, and the second nodal vibration region is located adjacent to the rectangular aperture.

In some embodiments, the rigid connecting member includes a first portion extending from the first nodal vibration region of the transducer body in a direction perpendicular to an axial direction of the transducer body, and a second portion (a long supporting arm) extending from the first portion along the axial direction of the transducer body till the second portion is connected to the mounting flange. The rigid connecting member is designed to increase the stiffness of the mounting flange and relieve the radial stress caused by the vibration of the transducer body during wire binding processes. Preferably, a length of the second portion of the rigid connecting member is approximately half of a wavelength of a sinusoidal ultrasonic signal being used to drive the ultrasonic transducer at the first resonant frequency.

In order to increase the bending stiffness of the ultrasonic transducer, a ratio Rh of a height of the first portion in a first direction perpendicular to the axial direction of the transducer body, e.g., z-axis direction, to a thickness of the second portion in a second direction perpendicular to the axial direction of the transducer body, e.g., x-axis direction, is selected such that: Rh²>Rb, wherein Rb refers to a predetermined ratio of a bending stiffness around the second direction to a bending stiffness about the first direction. In one embodiment, the predetermined ratio Rb is 10, accordingly, the height of the first portion in the second direction is not less than 3.2 times the thickness of the second portion in the first direction.

In some embodiments of the invention, the ultrasonic transducer may be operable at multiple resonant frequencies including the first resonant frequency. The first frequency is the highest resonant frequency thereof. In some embodiments of the invention, the first resonant frequency is up to 300 kHz.

In some embodiments, the ultrasonic transducer may be configured to operate at a second resonant frequency lower than the first resonant frequency. In order to further isolate the vibration of the transducer body from being transmitted to the wire bonding machine when the ultrasonic transducer is operated at the second resonant frequency, a first vibration point at the first nodal vibration region of the transducer body and a second vibration point at the second nodal vibration region have substantially equal vibration amplitudes and opposite vibration directions when the ultrasonic transducer is operated at the second resonant frequency. In other words, the rigid connecting member and the flexible connecting member are respectively attached to the first and second nodal vibration regions which have substantially equal vibration amplitudes and opposite vibration directions when the ultrasonic transducer is operated at the second resonant frequency. With the novel arrangement of the ultrasonic transducer, the second resonant frequency may be less than one third of the first resonant frequency.

In order to minimize the number of local bending modes that affect the operation shape of the ultrasonic transducer, at least one flexible or elastic preloading element is located on an internal surface of the aperture to form a preloading structure with non-uniform thickness in the aperture for generating a preload force on the piezoelectric driver stack.

In some embodiments of the invention, the mounting flange may include two parts that are symmetrically arranged on opposite sides of the transducer body, accordingly both the rigid connecting member and the flexible connecting member include two separate parts symmetrically arranged on opposite sides of the transducer body.

According to a second aspect of the present invention, there is provided an ultrasonic wire bonding device comprising the ultrasonic transducer according to various embodiments of the invention.

These and other features, aspects, and advantages will become better understood with regard to the description section, appended claims, and accompanying drawings.

### BRIEF DESCRIPTION OF THE DRAWINGS

Embodiments of the present invention will now be described, by way of example only, with reference to the accompanying drawings, in which:

FIG. 1A shows perspective and front views of a first prior art ultrasonic transducer.

FIG. 1B shows a top view of a second prior art ultrasonic transducer.

FIG. 1C shows a top view of a third prior art ultrasonic transducer,

FIG. 2A and FIG. 2B respectively show perspective and top views of an ultrasonic transducer according to one preferred embodiment of the invention.

FIG. 20 is a top view of an ultrasonic transducer according to an alternative embodiment of the invention.

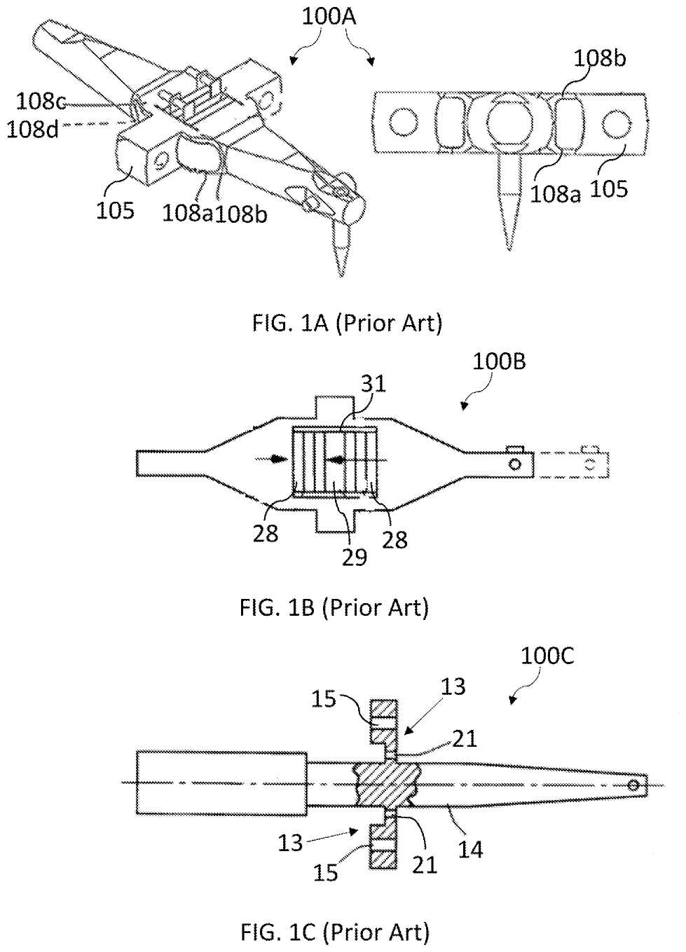

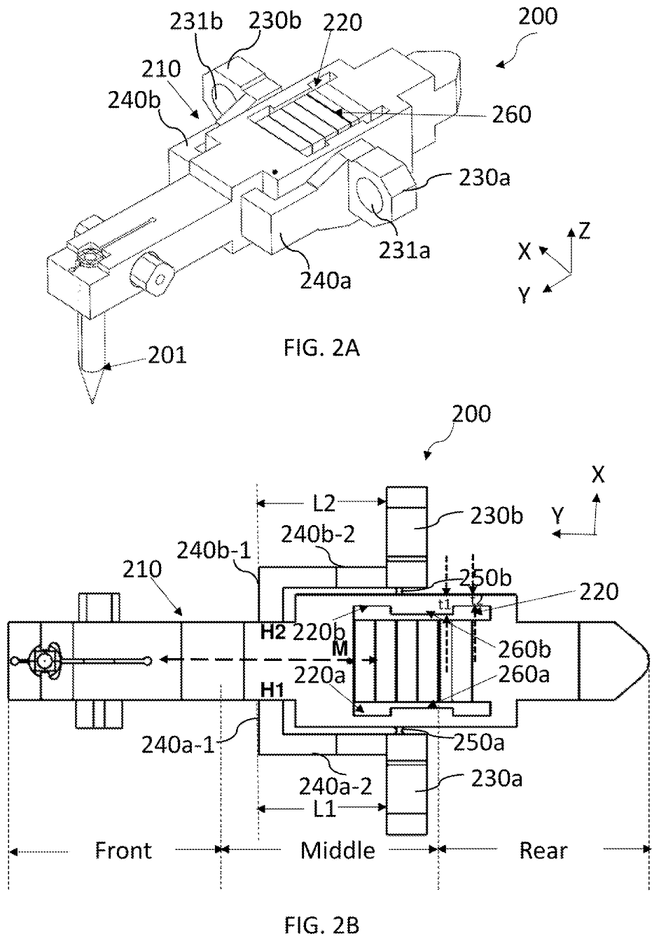

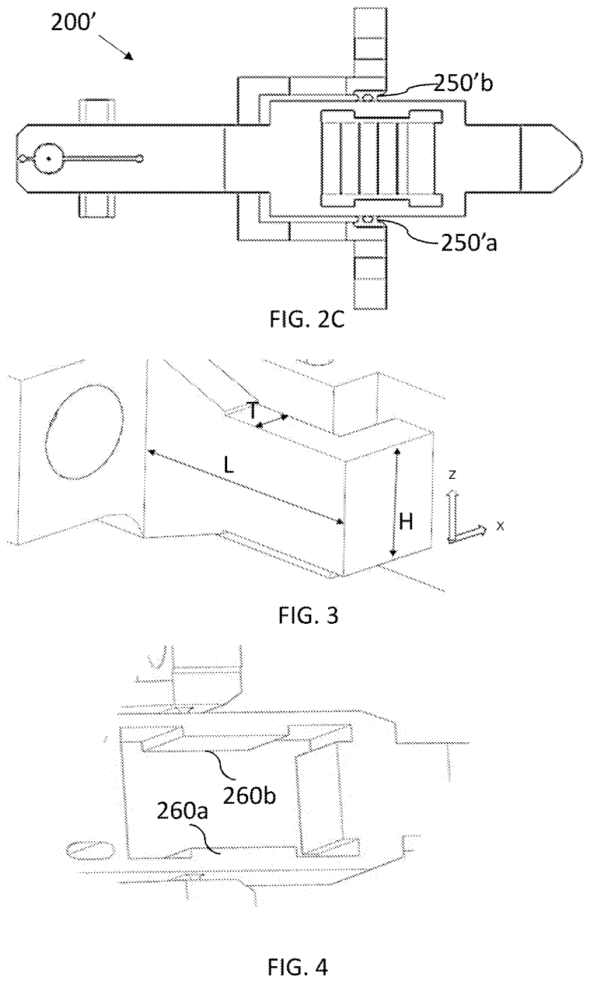

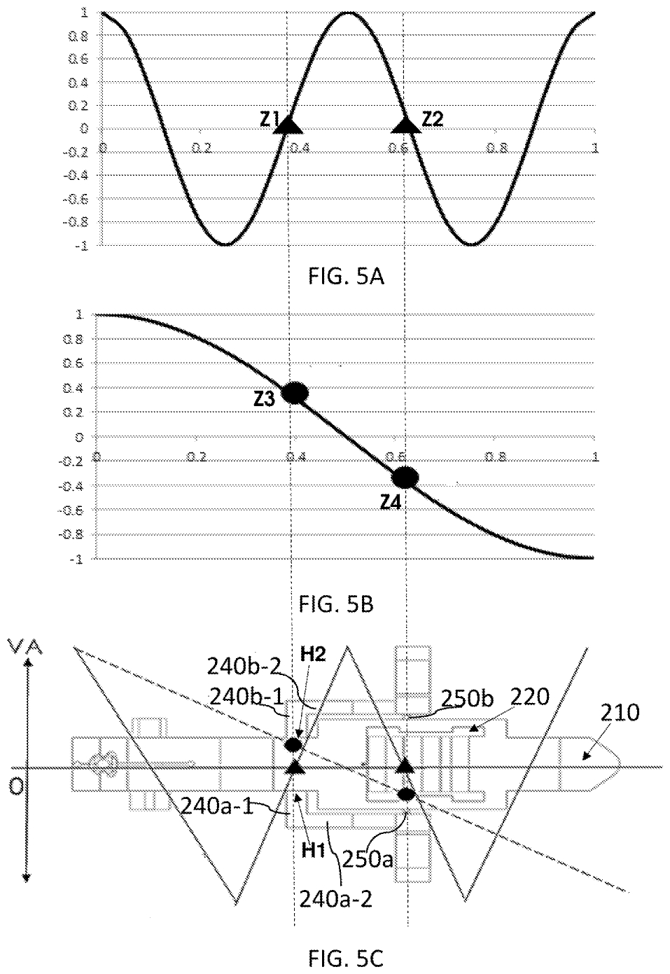

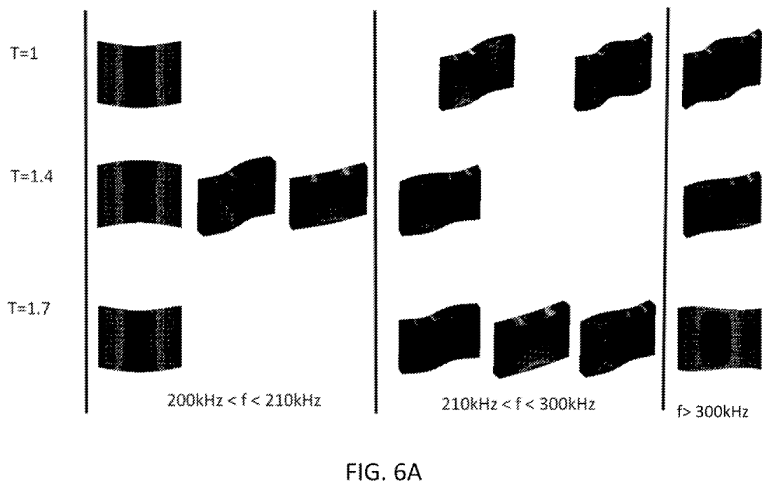

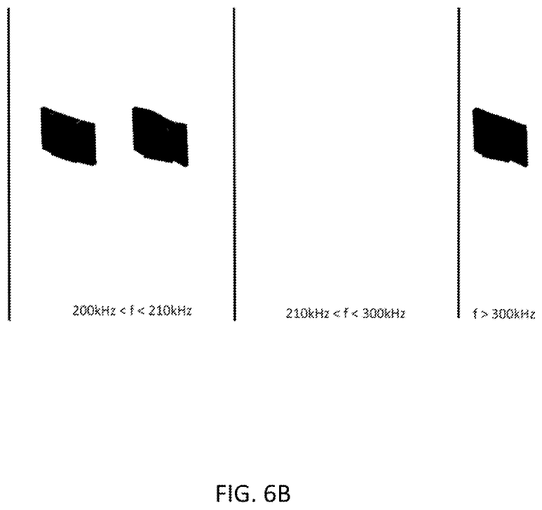

FIG. 3 is an enlarged perspective view of a rigid connecting member of the ultrasonic transducer as shown in FIG. 2A.

FIG. 4 is an enlarged perspective view of a preloading structure with non-uniform thickness in an aperture of the ultrasonic transducer as shown in FIG. 2A.

FIGS. 5A-5B respectively show schematic waveforms of displacement versus length of the transducer body when the ultrasonic transducer is operated at the first (higher) and the second (lower) resonant frequencies. FIG. 5C shows a top view of the ultrasonic transducer with the schematic waveforms as shown in FIG. 5A and FIG. 5B indicating vibration amplitudes of the ultrasonic transducer when it is operated at the lower and higher resonant frequencies.

FIG. 6A shows simulation results of vibration shapes of an ultrasonic transducer with a preloading structure having a uniform thickness.

FIG. 6B shows simulation results of vibration shapes of an ultrasonic transducer with a preloading structure having a non-uniform thickness.

In the drawings, like parts are denoted by like reference numerals.

### DETAILED DESCRIPTION OF THE PREFERRED EMBODIMENTS OF THE INVENTION

NG. 2A and FIG. 2B respectively show perspective and top views of an ultrasonic transducer 200 according to one preferred embodiment of the invention. The ultrasonic transducer 200 is operable at multiple frequencies. The multiple frequencies include a first (higher) resonant frequency and a second (lower)resonant frequency.

As shown in FIGS. 2A and 2B, the ultrasonic transducer 200 includes an elongated transducer body 210 with a rectangular aperture 220, a mounting flange including first and second flange elements 230a. 230b, a rigid connecting member including first and second rigid connecting elements 240a, 240b, and a flexible connecting member including first and second flexible connecting elements 250a, 250b.

The elongated transducer body 210 has one end to which a bonding tool 201 of a wire bonding machine is mounted. One benefit is that ultrasonic scrub assist may be added to pressure and heat during the bonding process to form a thermosonic bond with the bonding tool 201. As shown in FIG. 2B, the transducer body 210 generally includes three portions, i.e., front, middle and rear portions. The rectangular aperture 220 is approximately located between the middle and rear portions of the transducer body 210. The center of mass M of the ultrasonic transducer 200 is indicated in FIG. 2B, which is noticeably not located at the center of the rectangular aperture 220. The rectangular aperture 220 is adapted for mounting a piezoelectric driver stack 260 of the ultrasonic transducer 200 for driving the ultrasonic transducer 200 to operate at the multiple frequencies.

The mounting flange is provided for mounting the transducer body 210 to a wire bonding machine. The mounting flange in this embodiment includes the first flange element 230a and the second flange element 230b. The first and second flange elements 230a, 230b are symmetrically disposed on opposite sides of the transducer body 210. Each flange element 230a, 230b includes a mounting hole 231a, 231b for receiving a screw in order to mount the transducer body 210 to a wire bonding machine.

The rigid connecting member is provided to establish a rigid connection between the transducer body 210 and the mounting flange to improve the stiffness of the ultrasonic transducer 200. In this embodiment, the rigid connecting member includes the first and second rigid connecting elements 240a, 240b. Referring to FIGS. 2A and 2B, the first rigid connecting element 240a has a first end that is connected to the transducer body 210 at a first point H1 at a first nodal vibration region of the transducer body 210 when the ultrasonic transducer 200 is operated at the higher resonant frequency, and a second end that is connected to the first flange element 230a. The second rigid connecting element 240b has a first end that is connected to the transducer body 210 at a second point H2 at the first nodal vibration region of the transducer body 210 when the ultrasonic transducer 200 is operated at the first resonant frequency. The first point H1 and the second point H2 are located on opposite sides of the transducer body 210. A nodal vibration region refers to a region of the transducer body 210 that has a lower vibration amplitude compared to other (non-nodal) regions of the transducer body 210, e.g., a vibration amplitude that is not higher than 10% of the maximum vibration amplitude of the transducer body 210 when the ultrasonic transducer 200 is operated at the first resonant frequency. A method for determining the first nodal vibration region of the transducer body 210 will be explained below.

Referring to FIG. 2A and FIG. 2B, the first rigid connecting element 240a includes a first portion 240a-1 and a second portion 240-2. The first portion 240-1 extends from the first point H1 on the transducer body 210 in an X-axis direction that is perpendicular to an axial direction (or Y-axis direction) of the transducer body 210, and the second portion 240a-2 extends from an end of the first portion 240a-1 along a direction parallel to the axial direction of the transducer body 210, i.e., along the Y-axis direction. The second portion 240a-2 is then connected to the first flange element 230a emanating from the transducer body 210. Similarly, the second rigid connecting element 240b includes a first portion 240b-1 and a second portion 240b-2. The first portion 240b-1 extends from the second point H2 on the transducer body 210 in the X-axis direction and the second portion 240b-2 extends from an end of the first portion 240b-1 along the Y-axis direction. The second portion 240b-2 is connected to the second flange element 230b emanating from the transducer body 210.

When the ultrasonic transducer 200 is actuated to vibrate along the axial direction of the transducer body 210, a radial stress generated by the compression and extension of a horn of the transducer body 210 will be transmitted to the mounting flange through the rigid connecting member 240a. 240b. As the second portion 240a-2, 240b-2 of the rigid connecting member 240a, 240b is designed to provide bending degrees of freedom, the radial stress caused by vibration of the transducer body 210 is configured to be reduced by a deformation of the second portion 240a-2, 240b-2 when it bends. When the second portion 240a-2, 240b-2 is of a sufficient length, the radial stress may be reduced drastically at the mounting flange. In this embodiment, the length L1, L2 of the second portion 240a-2 and 240b-2 is approximately half of a wavelength of a sinusoidal ultrasonic signal being used to drive the ultrasonic transducer 200 at the first resonant frequency. Preferably, the length L1 of the second portion 240a-2 is substantially equal to the length L2 of the second portion 240b-2.

FIG. 3 is an enlarged perspective view of the rigid connecting member of the ultrasonic transducer 200 as shown in FIG. 2A. To improve the stiffness of the ultrasonic transducer 200, the rigid connecting member is designed to enhance a bending stiffness Bx about the X-axis direction of the ultrasonic transducer 200 but to weaken a bending stiffness Bz about the Z-axis direction for stress relief. Accordingly, a ratio Rh of a height H of the first portion 240b-1 in the Z-axis direction to a thickness T of the second portion 240b-2 in the X-axis direction may be determined based on a predetermined ratio Rb of Bx to Bz. Specifically, Bx is related to TH³ and Bz is related to HT³, the ratio Rh accordingly may be determined according to the formula Rh²>Rb. In one example, the predetermined ratio Rb is 10, the ratio Rh of H to T can be calculated according to the equations below:

Rb=Bx/Bz=TH³/HT³=(H/T)²

Rh=H/T=Rb^{1/2}>10^{1/2}=3.16≈3.2.

In this embodiment, to ensure that the ultrasonic transducer 200 has sufficient stiffness, the height H of the first portion 240b-1 in the Z-axis direction may be at least 3.2 times the thickness T of the second portion 240b-2 in the X-axis direction.

Referring to FIG. 2B, the flexible connecting member includes the first and second flexible connecting elements 250a, 250b. The first flexible connecting element 250a extends between the first flange element 230a and the transducer body 210 and the second flexible connecting element 250b extends between the second flange element 230b and the transducer body 210. The first and second flexible connecting elements 250a, 250b are respectively located on the transducer body 210 at first and second points of a second nodal vibration region of the transducer body 210 when the ultrasonic transducer 200 is operated at the first resonant frequency.

FIG. 2C is a top view of an ultrasonic transducer 200′ according to an alternative embodiment of the invention. It is different from the ultrasonic transducer 200 shown in FIG. 2B in that each flexible connecting element 250′a, 250′b includes two flexures extending between each mounting flange and the transducer body 210, instead of one.

The ultrasonic transducer 200 may further include at least one flexible or elastic preloading element located on an internal surface of the aperture 220 to form a preloading structure with non-uniform thickness within the aperture 220 for preloading the piezoelectric driver stack 260. In this embodiment, referring to FIG. 2B and FIG. 4, the flexible preloading member includes a first preloading element 260a extending or protruding from a middle part of an internal surface 220a of the aperture 220 and a second preloading element 260b extending or protruding from the internal surface 220b of the aperture 220. The flexible preloading member located on the internal surfaces 220a, 220b of the rectangular aperture 220 forms a non-uniform preloading structure or flexure in the rectangular aperture 220 to further reduce undesirable bending of the transducer body 210 when the ultrasonic transducer 200 is operated at the higher resonant frequency.

As shown in FIG. 2B, the non-uniform preloading structure in this embodiment includes a section having a first thickness t1 and other sections having a second thickness t2. Specifically, the first and second preloading elements 260a, 260b have the first thickness t1 which is greater than the second thickness t2 of other sections of the preloading structure. The non-uniform preloading structure provides more freedom for selecting attachment points for the flexible connecting members 250a, 250b so as to minimize vibration and rotation of the transducer body 210, thereby significantly eliminating undesirable bending of the transducer body 210 when the ultrasonic transducer 200 is operated at the first resonant frequency. In other words, the preloading structure having a non-uniform thickness can minimize the number of local bending modes that affect the shape of the ultrasonic transducer 200 during operations. The non-uniform preloading structure is designed such that the flexures 250a, 250b are attached to positions on the transducer body 210 which have a minimum bending vibration. Therefore, the arrangement of the non-uniform preloading structure on the internal surface of the aperture 220 can minimize the mounting impedance of the ultrasonic transducer 200 when it is operated at the first resonant frequency.

The method for determining the first and second nodal vibration regions of the transducer body 210 will now be explained. Both the first and second nodal vibration regions are selected based on a predetermined vibration amplitude of the transducer body 210 when the ultrasonic transducer 200 is operated at the first resonant frequency. In this embodiment, the selected first and second nodal vibration regions have vibration amplitudes that are not higher than 10% of the maximum vibration amplitude of the transducer body 210 when the ultrasonic transducer 200 is operated at the first (higher) resonant frequency.

Furthermore, the first and second nodal vibration regions may also be determined leased on a displacement waveform against length of the ultrasonic transducer 200 when the ultrasonic transducer 200 is operated at the first and second resonant frequencies. FIGS. 5A-5B respectively show schematic displacement waveforms against length of the transducer body 210 when the ultrasonic transducer 200 is operated at the first (higher) and the second (lower) resonant frequencies respectively. FIG. 5C shows a top view of the ultrasonic transducer 200 with the schematic waveforms as shown in FIG. 5A and FIG. 5B indicating vibration levels or vibration amplitudes at each region of the ultrasonic transducer 200 when it is operated at the first and second resonant frequencies. Referring to FIG. 5A, the first nodal vibration point H1, H2 is determined based on the first node Z1 and the second nodal vibration region is determined based on the second node Z2. The first nodal vibration region is a region around the first node Z1, this region having a vibration amplitude that is less than a predetermined vibration amplitude, e.g., less than 0.1 of the maximum vibration amplitude of the transducer body 210 when the ultrasonic transducer 200 is operated at the first resonant frequency. The second nodal vibration region is a region around the second node Z2, and this region also has a vibration amplitude that is less than the predetermined vibration amplitude. Referring to FIGS. 2B and 5C, the first nodal vibration region is located closer to the end coupled to the bonding tool 201 as compared with the second nodal vibration region, and the second nodal vibration region is located adjacent to the rectangular aperture 220.

Referring to FIGS. 5A and FIG. 5C, when the ultrasonic transducer 200 is operated at the first resonant frequency, the rigid connecting member is attached to the first and second points H1, H2 of the transducer body 210 where the transducer body 210 has the lowest vibration amplitude. In order to increase the stiffness of the ultrasonic transducer 200, in an approach that is different from the prior art transducer in which stress-relief slots on the mounting flange or the transducer body are used to relieve radial stress, a long solid arm separate from the mounting flange and the transducer body 210 (i.e., the second portion 240a-2, 240b-2 of each rigid connecting member 240a, 240b) is used to relieve the radial stress. To further increase the stiffness of the mounting flange, the flexible connecting member including at least one flexure is used to connect the mounting flange and the transducer body 210. With these two connection points which are spaced along the transducer body 210, the rotational stiffness of the ultrasonic transducer 200 can be further improved. The flexible connecting member (i.e., the flexures 250a, 250b) is attached to the second nodal vibration region to achieve a minimum vibration, especially a low bending moment around the flexures 250a, 250b.

Referring to 5B and 5C, when the ultrasonic transducer 200 is operated at the second resonant frequency, the vibration levels or vibration amplitudes of the vibration at the first and second nodal vibration regions of the transducer body 210 (e.g., the vibration amplitudes at Z3, Z4 are higher than the vibration amplitudes of the vibration at the first and second nodal vibration regions of the transducer body 210 (e.g., the vibration amplitudes at Z1, Z2) when the ultrasonic transducer 200 is operated at the higher resonant frequency. However, the vibrations at the first and second nodal vibration regions have substantially equal amplitudes and are in opposite vibrational directions.

That is to say, when the ultrasonic transducer 200 is operated at the second resonant frequency, the connection points of the rigid connecting member and the flexible connecting member are vibrating in opposite directions with the same vibration amplitude. With the opposite vibrational directions, a minimum vibration region that is suitable for the mounting flange can be identified. With the flexible connecting member, i.e., the flexures 250a, 250b extending between the mounting flange and the transducer body 210, the vibration of the transducer body 210 will be isolated from the neighboring region, especially to the rest of the bonding machine. The vibration at the mounting flange will be significantly reduced, thereby achieving a reduced mounting impedance for lower resonance actuation.

FIG. 6A shows simulation results of vibration shapes of an ultrasonic transducer with a preloading structure having a uniform thickness when the ultrasonic transducer is operated at a frequency fin the range of 200 kHz<f<210 kHz, 210 kHz<f<300 kHz, and f>300 kHz respectively. The simulation results for the preloading structure with a uniform thickness T=1 mm, 1.4 mm or 1.7 mm have been set out in FIG. 6A. The number of vibration shapes that appears in the frequency range is used to indicate the vibration level of the transducer body when it is operated at different frequency ranges. Referring to FIG. 6A, when the thickness T is 1 mm, there are four vibration shapes in the frequency range greater than 200 kHz; when the thickness T is 1.4 mm or 1.7 mm, there are five vibration shapes in the frequency range greater than 200 kHz. In particular, there is at least one vibration shape in the high frequency range from 200 kHz to 300 kHz regardless of the value of the thickness of the preloading structure.

FIG. 6B shows simulation results of vibration shapes of an ultrasonic transducer with a preloading structure having a non-uniform thickness when the ultrasonic transducer is operated at a frequency fin the range of 200 kHz<f<210 kHz, 210 kHz<f<300 kHz, and f>300 kHz. As shown in FIG. 6B, the total number of vibration shapes that appear in the frequency range greater than 200 kHz is three, less than the number of vibration shapes that appear in the frequency range greater than 200 kHz when the preloading structure has a uniform thickness. Specifically, two vibration shapes appear in the resonant frequency range of 200 kHz<f<210 kHz, one in the range of f>300 kHz, and no vibration shape appears in the high resonant frequency range of 210 kHz<f<300 kHz. Therefore, the simulation results prove that the non-uniform preloading structure is significantly effective for eliminating the vibration of the transducer body, especially when the ultrasonic transducer is operated at a high resonant frequency of up to 300 kHz.

As will be appreciated from the above description, embodiments of the invention provide an ultrasonic transducer that may be operable at multiple resonant frequencies, including an ultra-high resonant frequency of up to 300 kHz. Compared to prior art ultrasonic transducers, the ultrasonic transducer provided in embodiments of the invention has an improved bending stiffness since a rigid connecting member is used to connect a first nodal vibration region when the ultrasonic transducer is operated at a higher resonant frequency with the mounting flange. Also, the rigid connecting member includes a long supporting arm extending along an axial direction of the transducer body for radial stress relief. Furthermore, the mounting flange is connected to a second nodal vibration region when the ultrasonic transducer is operated at the higher resonant frequency through a flexible connecting member to further increase the bending stiffness of the mounting flange and to isolate vibrations from the rest of the bonding machine through the mounting flange. The first and second nodal vibration regions are selected such that the vibrations at these two regions have substantially equal vibration amplitudes and opposite vibration directions when the ultrasonic transducer is operated at the lower resonant frequency, thus the vibration transmitted from the transducer body to the mounting flange will be balanced and negated when the ultrasonic transducer is operated at the lower resonant frequency. The proposed ultrasonic transducer can therefore maintain an effective mounting while maintaining distinct vibration modes regardless of which operating resonant frequency it is operated at. In addition, a non-uniform thickness preloading structure is provided in the aperture of the ultrasonic transducer to control local bending modes that affect the operational stiffness of the ultrasonic transducer so as to minimize the mounting impedance of the ultrasonic transducer when it is operated at the higher resonant frequency.

According to embodiments of the invention, the mounting flange is not required to be attached to a common nodal displacement region of the higher and the lower resonant frequencies. Also, the piezoelectric driver stack need not be located at the center of mass of the ultrasonic transducer. In other words, it is not necessary to design the ultrasonic transducer such that the center of mass thereof is coincident with the center of the aperture of the ultrasonic transducer. Due to these arrangements, the selectable ranges of actuation frequencies of higher resonant and lower resonant frequencies are greatly improved compared to the ultrasonic transducers in prior art. Specifically, in prior art ultrasonic transducers, the higher resonant frequency must be less than 3 times the lower resonant frequency for higher resonance mode at 200 kHz to 300 kHz in order to obtain a pure axial actuation with high bending stiffness due to the structure and arrangement of the ultrasonic transducer. However, with the ultrasonic transducer provided in the embodiments of the invention, the higher resonant frequency may be more than 3 times of the lower resonant frequency.

Although the present invention has been described in considerable detail with reference to certain embodiments, other embodiments are possible. Therefore, the spirit and scope of the appended claims should not be limited to the description of the embodiments contained herein.

1. An ultrasonic transducer configured to operate at a first resonant frequency during wire bonding operations, the ultrasonic transducer comprising:
an elongated transducer body with an aperture for mounting a piezoelectric driver stack for driving the ultrasonic transducer to operate at the first resonant frequency,
a mounting flange for mounting the transducer body to a wire bonding machine,
a rigid connecting member having first and second ends which are respectively connected to the mounting flange and the transducer body at a first nodal vibration region of the transducer body when the ultrasonic transducer is operated at the first resonant frequency, and
a flexible connecting member extending between the mounting flange and the transducer body at a second nodal vibration region of the transducer body when the ultrasonic transducer is operated at the first resonant frequency.

2. The ultrasonic transducer according to claim 1, wherein the rigid connecting member includes a first portion extending from the first nodal vibration region of the transducer body in a direction perpendicular to an axial direction of the transducer body, and a second portion extending from the first portion along the axial direction of the transducer body, the second portion being connected to the mounting flange.

3. The ultrasonic transducer according to claim 2, wherein a length of the second portion of the rigid connecting member is approximately half of a wavelength of a sinusoidal ultrasonic signal being used to drive the ultrasonic transducer at the first resonant frequency.

4. The ultrasonic transducer according to claim 2, wherein a ratio Rh of a height of the first portion in a first direction perpendicular to the axial direction of the transducer body to a thickness of the second portion in a second direction perpendicular to the axial direction of the transducer body is selected such that: Rh²>Rb, where Rb refers to a predetermined ratio of a bending stiffness around the second direction to a bending stiffness about the first direction.

5. The ultrasonic transducer according to claim 4, wherein the predetermined ratio is 10, and the height of the first portion in the second direction is not less than 3.2 times the thickness of the second portion in the first direction.

6. The ultrasonic transducer according to claim 1, wherein the first and the second nodal vibration regions of the transducer body have a vibration amplitude not higher than 10% of a maximum vibration amplitude thereof when the ultrasonic transducer is operated at the first resonant frequency.

7. The ultrasonic transducer according to claim 1, wherein the first nodal vibration region is located closer to a bonding tool compared to the second nodal vibration region, and the second nodal vibration region is located adjacent to the rectangular aperture.

8. The ultrasonic transducer according to claim 1, wherein the ultrasonic transducer is further configured to operate at a second resonant frequency lower than the first resonant frequency, and wherein a first vibration point at the first nodal vibration region of the transduce body and a second vibration point at the second nodal vibration region have substantially equal and opposite vibration amplitudes when the ultrasonic transducer is operated at the second resonant frequency.

9. The ultrasonic transducer according to claim 8, wherein the second resonant frequency is less than one third of the first resonant frequency.

10. The ultrasonic transducer according to claim 1, further comprising at least one flexible or elastic preloading element having a non-uniform thickness located on an internal surface of the aperture to form a preloading structure in the aperture for generating a preload force on the piezoelectric driver stack.

11. The ultrasonic transducer according to claim 1, wherein the rigid connecting member and the flexible connecting member are integrally formed with the transducer body.

12. The ultrasonic transducer according to claim 1, wherein the mounting flange includes first and second flange elements that are disposed symmetrically on opposite sides of the transducer body,
the rigid connecting member includes first and second rigid connecting elements that are arranged symmetrically on opposite sides of the transducer body, each rigid connecting element having first and second ends, and
the flexible connecting member includes a first flexible connecting element extending between the first flange element and the transducer body, and a second flexible connecting element extending between the second flange element and the transducer body.

13. The ultrasonic transducer according to claim 12, wherein the first end of the first rigid connecting element is connected to the transducer body at a first point at the first nodal vibration region, and the second end of the first rigid connecting element is connected to the first flange element, and
the first end of the second rigid connecting element is connected to a second point at the first nodal vibration region, and the second end of the second rigid connecting element is connected to the second flange element,
and wherein the first and second points of the first nodal vibration region are symmetrically located on opposite sides of the transducer body.

14. The ultrasonic transducer according to claim 12, wherein the first and second flexible connecting elements are respectively located at first and second points of the second nodal vibration region on the transducer body, the first and second points of the second nodal vibration region being symmetrically located on opposite sides of the transducer body.

15. The ultrasonic transducer according to claim 12, wherein the first flexible connecting element includes at least one flexure extending between the first flange element and the transducer body, and the second flexible connecting element includes at least one flexure extending between the second flange element and the transducer body.

16. The ultrasonic transducer according to claim 1, wherein the first resonant frequency is up to 300 kHz.

17. An ultrasonic wire bonding device comprising an ultrasonic transducer according to claim 1.
